(19) United States
(12) Patent Application Publication
(10) Pub. No.: US 2025/0362358 A1
(43) Pub. Date: Nov. 27, 2025

(54) JUMPER WIRE, MODULE AND METHOD FOR DIAGNOSING THE STATE OF HEALTH OF A PLURALITY OF ELECTRICAL CABLES

(71) Applicant: SAFRAN AIRCRAFT ENGINES, PARIS (FR)

(72) Inventors: Gilles POLO FILISAN, MOISSY-CRAMAYEL (FR); Taous BOUMAZA, MOISSY-CRAMAYEL (FR); Gwénaëlle CASSAR, MOISSY-CRAMAYEL (FR); Yann HEZARD, MOISSY-CRAMAYEL (FR)

(21) Appl. No.: 18/867,854

(22) PCT Filed: May 22, 2023
(86) PCT No.: PCT/EP2023/063623

§ 371 Date: Nov. 21, 2024

(30) Foreign Application Priority Data
May 24, 2022 (FR) FR2204969

(51) Int. Cl. G01R 31/58; G01R 31/00; G01R 31/54

(52) U.S. Cl. CPC G01R 31/58; G01R 31/008; G01R 31/54

(57) ABSTRACT

A jumper wire for connecting an electrical cable to a test device with a view to diagnosing the state of health of the electrical cable. The jumper wire includes an output port configured to interact with an input port of the test device, an input connector configured to interact with a connector of the electrical cable, and a data-storing element that contains predetermined test data on the electrical cable and that is electrically connected to the output port by at least one data-transmitting wire. The data-storing element being is configured to deliver the test data to the test device.

### TECHNICAL FIELD

The present invention relates to the field of diagnosing the state of health of a plurality of electrical cables, in particular in an aircraft during maintenance.

It is well known that an aircraft comprises a multitude of electrical cables, in particular harnesses referred to as “electrical harnesses” or “electrical distribution routes”. Each electrical cable is dimensioned to transport electrical energy from a power supply cabinet towards an aircraft equipment, referred to as an “electrical load”. The aircraft equipment takes the form of sensors and actuators, for example, mounted in the turbomachine of one or more aircraft propulsion units to control speed.

In a known way, each electrical cable comprises an assembly of electrical wires, referred to as “strands”, grouped together by a protective sheath. Each electrical cable comprises an input connector connected to the power supply cabinet and an output connector connected to the aircraft equipment to provide its electric power supply. The electrical cable is installed in the aircraft and attached to the structure using hose clamps and retaining clips.

In practice, during maintenance, it is necessary to check the state of health of all the electrical cables, which means for each cable checking the electrical continuity and insulation of each electrical wire. The continuity check consists of checking that the electrical wire is not interrupted or damaged between the connectors. The electrical insulation check consists of verifying that the electrical wire is not in electrical contact with a neighboring electrical wire, which could generate a short-circuit.

Such maintenance is time-consuming and error-prone, given the number and complexity of the electrical cables. In addition, it must be carried out on board the aircraft to avoid time-consuming and costly cable removal and any risk of error during reassembly. Another difficulty is that electrical cable connectors are not universal, but depend on both the turbomachine and the electrical equipment they connect. In practice, there are many different types of cable with specific input and/or output connectors.

The patent application FR3078791A1 describes a portable diagnostic device for carrying out electrical tests on the electrical cables of an aircraft turbomachine. The diagnosis is carried out cable by cable. The cable is disconnected from the equipment to which it is connected and then connected to the diagnostic device via a dedicated jumper wire, acting as an adapter between a connector on the cable and an input connector on the diagnostic device. This means there are as many jumper wires as there are cable types. The identification data of the cable is entered manually into the diagnostic device via a man-machine interface, so that the appropriate test program may be selected for the cable to be checked.

In practice, such maintenance requires a large number of manual operations, which is time-consuming and a source of errors given the number of cables to be tested. In particular, an error in the identification data entry may lead to an incorrect selection of the test program, and consequently provide an inconsistent state of health of the electrical cable, or even in some cases degrade the electrical cable.

Another disadvantage of such a diagnostic device is that it may not be upgraded. For each new type of cable not listed in the diagnostic device, it is necessary to provide a software update for the diagnostic device in order to have a suitable test program, which means sending it back to the manufacturer.

Also known from the patent applications EP1149292A1 and EP2643703A1 is a diagnostic device with several inputs allowing several electrical cables to be connected simultaneously. Such a solution is bulky, which is undesirable.

Also known from the patent application EP2273278A2 is a test system with adapters which are connected to a combination of electrical contacts of the test system, determined by successive tests. This requires a switching matrix and does not solve the overall dimension problem mentioned above.

The invention aims to eliminate at least some of these disadvantages.

### PRESENTATION OF THE INVENTION

The invention relates to a jumper wire for connecting an electrical cable to a test device for diagnosing the state of health of the electrical cable, said jumper wire comprising:
an output port configured to cooperate with an input port of the test device and
an input connector configured to cooperate with a connector of the electrical cable, the input connector being electrically connected to the output port.

The invention is notable in that the jumper wire comprises at least one data-storing element comprising predetermined test data of the electrical cable, said data-storing element being electrically connected to the output port by at least one data-transmitting wire, said data-storing element being configured to provide the test data to the test device.

The jumper wire thus comprises two functions, namely to provide the electrical interconnection between the electrical cable and the test device on the one hand, and to transmit the test data from the electrical cable to the test device on the other.

It is advantageous to use the jumper wire according to the invention to reduce the number of manual operations required when maintaining an electrical cable. The data-storing element automatically transmits to the test device the test data required to implement maintenance (electrical cable references, voltage and current values, etc.). This eliminates the need for the operator to manually enter test data into the test device, which saves time. This also avoids the risk of errors when entering data. In addition, the test data is more accurate than a cable identification information as in the prior art, allowing more precise and reliable tests to be carried out.

In addition, no specific operation is required to connect the data-storing element to the test device. The data-storing element is wired to the output port of the jumper wire so that its connection to the test device ensures that the data-storing element is connected to the test device.

According to one aspect of the invention, the input connector of the jumper wire is configured to pair up by shape complementarity only with the connector of the electrical cable whose test data is stored in the data-storing element. Advantageously, this ensures mechanical keying. The physical compatibility of the connectors on the jumper wire and the electrical cable allows to ensure that the test data transmitted is that relating to the electrical cable connected and not another. This avoids the need to check that the stored test data matches that of the connected electrical cable.

According to one aspect of the invention, the jumper wire comprises at least one power supply lead connecting the data-storing element to the output port, allowing a power supply of the data-storing element by the test device when the jumper wire is connected thereto. This makes powering the data-storing element simple and convenient: connecting the output port of the jumper wire to the test device allows both the test data to be transmitted and power to be supplied to the data-storing element.

According to one aspect of the invention, the jumper wire comprises at least one electrical test lead connecting the output port to the input connector, the output port comprising a projecting segment comprising an inner face facing the electrical test lead, said data-storing element being positioned against the inner face of the projecting segment. The data-storing element is advantageously protected from external aggression, such as mechanical shocks. The same applies to data transmission and/or power supply leads.

According to a preferred aspect of the invention, the jumper wire comprises a sheath surrounding the electrical test lead, said data storage element being attached to the sheath. In this way, the data-storing element is simply and conveniently attached to a jumper wire. In particular, it is thus possible to make a jumper wire according to the prior art compatible and usable with a test device as presented in this application, by integrating such a data-storing element.

The invention also relates to a module for diagnosing the state of health of at least one electrical cable, said diagnostic module comprising a test device and at least one jumper wire as previously described, the test device comprising at least one input port cooperating with the output port of the jumper wire to connect them electrically in a removable manner, the input connector of the jumper wire being configured to cooperate with a connector of the electrical cable, the test device being configured for:
reading the test data stored in the data-storing element of the jumper wire, and
executing a test comprising:
   transmitting at least one test signal into the electrical cable via the jumper wire, the test signal being determined from the test data, and
   measuring at least one response signal of the electrical cable, via the jumper wire, so as to determine the state of health of the electrical cable.

Advantageously, the diagnostic module according to the invention allows a simple, fast and reliable maintenance of one or more different types of cable. By integrating a data-storing element in the jumper wire, the test data specific to the electrical cable may be automatically transmitted to the test device. This avoids having to enter or select them manually in the test device, saving time and reducing the risk of error during maintenance.

Advantageously, the diagnostic module allows maintenance of an electrical cable to be implemented autonomously. The diagnostic module of the invention is also advantageously upgradeable. To maintain a new type of electrical cable, all that's needed is a new jumper wire with a suitable input connector and a data-storing element configured with corresponding test data. There is no need to intervene or modify the test device itself, which is particularly advantageous and effective, both in terms of saving time and cost: no need to return to the factory to update the test device.

According to one aspect of the invention, the test data are in the form of at least one of the following elements: code data to be executed by said test device, the selection of a test to be executed from a list of tests of the test device and/or at least one test parameter for executing a test of the test device. Test data formats such as these help to make the diagnostic module scalable. The test data may be used to complete and/or select a generic test program stored in the test device, which allows to generate a very wide variety of possible tests, specific to each type of electrical cable.

According to one aspect of the invention, the data-storing element of the jumper wire also comprises validation data and the test device is configured for:
determining at least one reference signal from the validation data, and
comparing the response signal with the reference signal.

The data-storing element thus comprises two types of data specific to the electrical cable to be tested, namely test data allowing the test device to draw up the test program to be implemented, and validation data allowing the test device to analyze the measured response signals. Advantageously, the proposed diagnostic module allows measurements to be analyzed autonomously to provide the operator with a diagnosis of the state of health of an electrical cable. This means that the operator may make a simple, rapid diagnosis in situ, using this single module.

According to one aspect of the invention, the diagnostic module comprises a plurality of jumper wires, at least two jumper wires of which comprise a differently shaped input connector and different test data. Advantageously, each jumper wire may be used to connect and transmit test data specific to one type of electrical cable to the test device. The keying provided by the shape of the input connector on each jumper wire allows to ensure that the prerecorded test data matches that of the compatible electrical cable being tested.

According to a preferred aspect of the invention, the diagnostic module test device comprises a single input port configured to cooperate alternately with the output port of each jumper wire. This makes the test device particularly compact, with a single, universal input connector.

According to a preferred aspect of the invention, the diagnostic module is portable. A module of this type is particularly suitable for maintaining the electrical cables of an aircraft, especially the turbomachine, in situ. This allows to avoid time-consuming and costly cable removal operations, and avoids the risk of errors during reassembly.

The invention also relates to a method for manufacturing a jumper wire as previously described comprising:
a step of electrically connecting the data-storing element to the output port, and
a step of programming test data into the data-storing element.

These steps are advantageously simple, quick and inexpensive to implement. These steps could possibly be implemented on an existing jumper wire, for a given type of electrical cable, allowing it to be used with the test device of the present application.

The invention also relates to a method for diagnosing the state of health of at least one electrical cable by means of a jumper wire as previously described, test data of the electrical cable initially being stored in the data-storing element of the jumper wire, the diagnostic method comprising:
a step of connecting the jumper wire to a test device.
a step of connecting the jumper wire to the electrical cable,
a step of reading, by the test device, test data stored in the data-storing element of the jumper wire, and
executing a test comprising:
   a step of transmitting, by the test device, at least one test signal into the electrical cable via the jumper wire, the test signal ST being determined from the test data DT, and
   a step of measuring, by the test device, at least one response signal from the electrical cable, via the jumper wire, so as to determine the state of health of the electrical cable.

Advantageously, such a diagnostic method is quick and easy to implement. The test data relating to the electrical cable does not need to be entered or selected manually, as it is transmitted immediately and automatically to the data-storing element. The reading step also makes the method more reliable in that it avoids errors associated with manual input of test data.

According to one aspect of the invention, the diagnostic method comprises a step of selecting a jumper wire whose input connector is configured to cooperate with the connector of the electrical cable. The diagnostic method is advantageously compatible with a wide range of cable types, by providing the appropriate jumper wire.

According to a preferred aspect of the invention, the diagnostic method comprises:
a step of reading, by the test device, the validation data stored in the data-storing element of the jumper wire,
a step of comparing, by the test device, the response signal with a reference signal determined from the validation data.

Advantageously, the diagnostic method allows the measured response signal to be analyzed in order to provide a diagnosis of the state of health of the electrical cable, using the same tool (diagnostic module) and in situ (without dismantling the cable). The diagnosis is also relevant because it is based on validation data specific to the electrical cable.

According to one aspect of the invention, the diagnostic method is implemented for at least one electrical cable in an aircraft propulsion assembly, said electrical cable initially connecting an aircraft computer to a turbomachine equipment, said diagnostic method comprising a preliminary step of disconnecting the connector of the electrical cable connecting it to the turbomachine equipment. Advantageously, such a diagnostic method avoids the need to remove the aircraft turbomachine, which saves time and avoids any risk of error during reassembly. In addition, the diagnostic method may advantageously be implemented for all harnesses with a single diagnostic module.

### PRESENTATION OF FIGURES

The invention will be better understood on reading the following description, given by way of example, with reference to the following figures, given by way of non-limiting examples, wherein identical references are given to similar objects.

FIG. 1 is a schematic representation of a module for diagnosing the state of health of turbomachine harnesses according to one embodiment of the invention.

FIG. 2 is a schematic representation of the diagnostic module of FIG. 1 in use.

FIG. 3 shows a longitudinal cross-section of a jumper wire of the diagnostic module in FIG. 1,

FIG. 4 is a schematic representation of a method for manufacturing the jumper wire of FIG. 3 according to one embodiment of the invention.

FIG. 5 is a schematic representation of the test device of the diagnostic module of FIG. 1.

FIG. 6 is a schematic representation of a method for diagnosing the state of health of a turbomachine harness according to one embodiment of the invention.

It should be noted that the figures set out the invention in detail in order to implement the invention, said figures of course being able to be used to better define the invention if necessary.

### DETAILED DESCRIPTION OF THE INVENTION

The invention concerns a device and a method for diagnosing the state of health of electrical cables. The invention is described below in the context of the aircraft electrical cable maintenance, for which the invention was developed. It goes without saying, however, that it may be applied to any type of electrical cable.

As described in the preamble, an aircraft comprises a multitude of electrical cables, in particular harnesses referred to as “electrical harnesses” or “electrical distribution routes”. Each electrical cable is dimensioned to transport electrical energy from a power supply cabinet towards an aircraft equipment, referred to as an “electrical load”. The aircraft equipment takes the form of sensors and actuators, for example, mounted in the turbomachine of one or more of the aircraft's propulsion units to control speed.

In a known way, each electrical cable comprises an assembly of electrical wires, referred to as “strands”, grouped together by a protective sheath. Each electrical cable comprises an input connector connected to the power supply cabinet and an output connector connected to the aircraft equipment to supply it with electrical power. The electrical cable is installed in the aircraft and attached to the structure by means of hose clamps and retaining clips.

In practice, the electrical cables are not universal, but depend in particular on the turbomachine and the equipment they connect. There are many different types of cable, each comprising its own specific input and/or output connectors. As an example, FIG. 2 schematically illustrates three electrical cables 100-A, 100-B, 100-C whose output connector 110-A, 110-B, 110-C is disconnected from the turbomachine equipment 400. Each output connector 110-A, 110-B, 110-C comprises a specific shape, different from the others. It should be noted that the shape as such of the output connectors 110-A, 110-B, 110-C is not intended to be realistic in FIG. 2. In practice, the shape of a connector 110 depends in particular on the number of contacts it comprises, equal to the number of electrical wires in the electrical cable 100.

In practice, during maintenance, it is necessary to check the state of health of all the electrical cables 100, which means checking the electrical continuity and insulation of each electrical wire. The continuity check consists of checking that the electrical wire is not interrupted or damaged between the connectors. The electrical insulation check consists of verifying that the electrical wire is not in electrical contact with a neighboring electrical wire, which could generate a short-circuit. These tests comprise measuring the electrical resistance of each wire of each cable 100. Preferably, a capacity test is also carried out for each wire to check the state of health of the cables 100. The capacitance check consists of measuring the capacitance value between each wire of the cable 100 and its internal shield, which is applied to a contact on the output connector 110.

To this end, with reference to FIGS. 2 and 3, the invention relates to a diagnostic module 1 comprising a test device 2 and one or more jumper wires 6. Each jumper wire 6 comprises:
an output port 7 configured to cooperate with an input port 3 of the test device 2, to connect electrically to the test device 2 in a removable manner,
an input connector 8 configured to cooperate with a connector 110 of an electrical cable 100 to be diagnosed, the input connector being electrically connected to the output port, and
a data-storing element 9 comprising predetermined test data DT of the electrical cable 100 and electrically connected to the output port 7 by at least one data-transmitting lead 12, the data-storing element 9 being configured to supply the test data DT to the test device 2.

Still according to the invention and with reference to FIGS. 2 and 3, the test device 2 is configured for:
reading the test data DT stored in the data-storing element 9 of the jumper wire 6,
executing a test comprising:
   transmitting a test signal ST into the electrical cable 100 via the jumper wire 6, the test signal ST being determined from the test data DT, and
   measuring at least one response signal SR of the electrical cable 100, via the jumper wire 6, so as to determine the state of health ES of the electrical cable 100.

In practice, the diagnostic module 1 comprises as many jumper wires 6 as there are types of electrical cables 100, so that all the aircraft's electrical cables 100, and in particular the turbomachine 500, may be maintained. In the example shown in FIG. 2, comprising three types of electrical cables 100-A, 100-B, 100-C, the diagnostic module comprises three jumper wires 6-A, 6-B, 6-C.

As illustrated in FIGS. 2 and 3, each jumper wire 6-A, 6-B, 6-C provides the electrical interconnection between an electrical cable 100-A, 100-B, 100-C of a given type and the test device 2. The diagnostic module 1 therefore requires only a single test device 2 to test all the cables 100. Each jumper wire 6-A, 6-B, 6-C also transmits test data DT specific to the electrical cable 100-A, 100-B, 100-C, such as the electrical cable references, test voltage and current values, etc. This avoids having to enter or select them manually in the test device 2. By way of example, the second jumper wire 6-B is used to connect the second electrical cable 100-B to the test device 2 and to transmit to it the test data DT-B relating to the second electrical cable 100-B.

Advantageously, the diagnostic module 1 may be upgraded. To test a new type of electrical cable, all that is required is a new jumper wire 6 equipped with the appropriate connector 8 and a data-storing element 9 configured with the cable-specific test data DT readable by the test device 2. There is no need to update the test device 2. The test data DT provides all the information necessary for the test device 2 to execute the appropriate test, i.e. to measure the electrical parameters of the cable 100. Preferably, the data-storing element 9 also comprises validation data DV allowing the measurements to be compared with reference data and thus conclusions to be drawn about the state of health of the electrical cable 100.

Preferably, the diagnostic module 1 consists solely of the test device 2 and the jumper wires 6-A, 6-B, 6-C. Advantageously, the diagnostic module 1 is portable, allowing maintenance to be carried out on board the aircraft. The cables 100 are simply disconnected from the aircraft equipment and connected to the test device 2 via the appropriate jumper wire 6-A, 6-B, 6-C. This avoids time-consuming and costly removal of the electrical cables 100, as well as the risk of errors during reassembly. The jumper wires 6 are preferably flexible to facilitate connection.

The structural and functional characteristics of the jumper wires 6 and the test device 2 are described in more detail below.

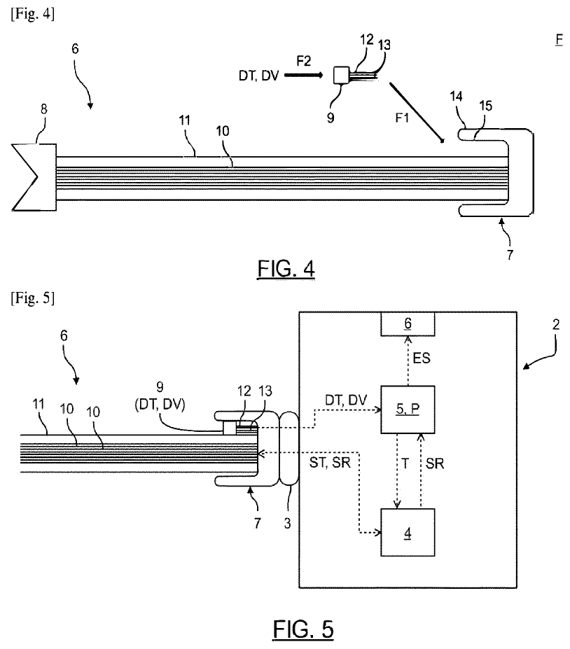

As shown in FIG. 4, each jumper wire 6 comprises electrical test leads 10 electrically connecting the input connector 8 to the output port 7. The electrical test leads 10 provide an electrical connection between the electrical cable 100 and the test device 2, and in particular ensure the transmission of the ballast ST and response SR signals.

As illustrated in FIG. 4, the data-storing element 9 is electrically connected to the output port 7 by data transmission leads 12. The data transmission leads 12 allow test data DT to be transmitted safely, reliably and quickly to the test device 2. In a preferred aspect, power supply leads 13 also connect the data-storing element 9 to the output port 7. This allows the data-storing element 9 to be powered by the test device 2 in a simple and practical way. In the example shown in FIG. 4, the power supply leads 13 are shown separately from the data transmission leads 12, but it goes without saying that they could be confused.

With reference to FIG. 4, the data-storing element 9 is mounted on the jumper wire 6. According to a preferred aspect, a protective sheath 11 surrounds the electrical test leads 10, to which the data-storing element 9 is attached. Preferably, the data-storing element 9 is mounted close to the output port 7, preferably less than 10 cm away, to reduce the length of the data transmission 12 and power supply 13 leads. By being as close as possible to the output port 7, the data-storing element 9 is protected by the armature of the output port 7 and from any electromagnetic interference.

According to a preferred aspect illustrated in FIG. 4, the output port 7 comprises a projecting segment 14, which projects towards the input connector 8. The projecting segment 14 comprises an inner face 15 facing the sheath 11 and the electrical test leads 10, which together define a housing wherein the data-storing element 9 is mounted. The data-storing element 9 thus extends against the inner face 15 of the projecting segment 14, providing protection in particular against impact. This also allows to protect the data transmission leads 12 and the power supply leads 13.

Preferably, the data-storing element 9 is in the form of an electronic chip comprising a programmable memory for storing the test data DT. Preferably, the memory is reprogrammable so that the test data DT may be modified. The test data DT preferably comprises one or more of the following content elements: references of the electrical cable 100, of the turbomachine and/or of the aircraft equipment, the number of the electrical cable 100, the number of contacts of the electrical cable 100, values of electrical test parameters (voltage, current). The test data DT is preferably in the form of one or more of the following: code data to be executed by the test device 2, the selection of a test to be executed from a list of tests of the test device 2 and/or one or more test parameters for executing a test of the test device 2.

With reference to FIGS. 3 and 4, according to a preferred aspect, the input connector 8 is configured to cooperate in a form-fitting manner with the connector 110 of the electrical cable 100 (keying function). The jumper wire 6 may thus be connected only to the electrical cable 100 corresponding to the one whose test data DT is stored in the data-storing element 9. The physical compatibility ensures that the test data DT transmitted to the test device 2 is that of the connected electrical cable 100.

By way of example, in FIG. 3, the second input connector 8-B is configured to cooperate in a form-fitting manner with the second connector 110-B of the second electrical cable 100-B, but not with those of the first electrical cable 100-A and the third electrical cable 100-C. Note that the actual shape of the input connectors 8-A, 8-B, 8-C is not intended to be realistic in FIGS. 2 to 5.

FIG. 5 illustrates a manufacturing method F for manufacturing the jumper wire 6, comprising a step of electrically connecting F1 the data-storing element 9 to the output port 7, and a step of programming F2 predetermined test data DT in the data-storing element 9. Advantageously, the data-storing element 9 may be mounted on an existing, i.e. passive and intelligence-free, jumper wire 6. Advantageously, the programming F2 is done during factory assembly, so that the jumper wire 6 is ready for use by the operator during maintenance.

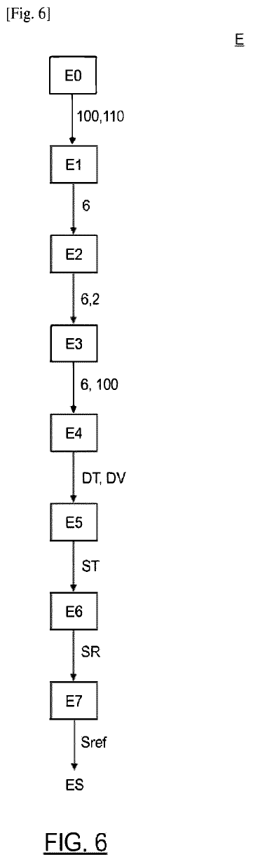

With reference to FIG. 6, the test device 2 comprises an input port 3 configured to cooperate with the output port 7 of each jumper wire 6. Preferably there is a single entry port 3, but each jumper wire 6 may be connected alternately.

According to a preferred aspect illustrated in FIG. 6, the test device 2 also comprises a measuring member 4, a control member 5 and a display member 6. The measuring member 4 takes the form of an electrical measuring apparatus, such as a voltmeter, an ammeter or a multimeter. The control member 5 is a microcontroller, for example. The display member 6 is in the form of a screen, for example.

As illustrated in FIG. 6, the control member 5 is configured to read the test data DT stored in the data-storing element 9 and to determine a specific test T of the electrical cable 100 to be checked. The test T specifies the protocol to be implemented to check the state of health of the electrical cable 100, and in particular the test signals ST to be transmitted to the electrical cable 100 to measure the electrical resistance of each wire, and preferably its shielding capacity, in order to check the insulation and the continuity of the electrical cable 100.

Preferably, the test T is determined from the test data DT and a test program P stored in the test device 2, in this example in the control member 5. In a first aspect, the test data DT is in the form of parameters which allow the test program P to be adapted to the electrical cable 100 to be checked. By choosing the value of one or more parameters, a wide range of different tests may be performed. In a second aspect, the test program P comprises a list of tests and the test data DT is used to identify the relevant test in the list. Advantageously, the test T may be determined very simply. According to a third aspect, the test data DT comprises code data allowing the test program P to be completed to define the test T. This last variant allows the test device 2 to be as scalable as possible, with an unlimited range of tests, preferably determined solely from the test data DT. The diagnostic module 1 may therefore autonomously determine the appropriate test and implement it automatically, without operator intervention.

As shown in FIG. 6, the control member 5 is configured to transmit the test T to the measuring member 4. The measuring member 4 is configured to execute the test T, i.e. to transmit the test signals ST via the jumper wire 6 to the electrical cable 100. The measuring member 4 acquires the response signals SR. in response to the test signals ST, via the jumper wire 6, and transmits them to the control member 5.

With reference to FIG. 6, the control member 5 is configured, on the basis of the response signals SR, to determine a state of health ES of the electrical cable 100, which is transmitted to the display member 6. Preferably, the control member 5 is configured to compare the response signals with one or more reference signals, defining for example a minimum and/or maximum tolerance threshold for electrical insulation and/or continuity.

According to a preferred aspect illustrated in FIG. 6, the reference signals are determined from validation data DV stored in the data-storing element 9 and specific to the electrical cable 100. The data-storing element 9 comprises both test data DT and validation data DV, both of which are transmitted to the control member 5. This allows to carry out individual checks on each electrical cable, increasing reliability. The display member 6 could also directly present the response signals SR as a state of health ES.

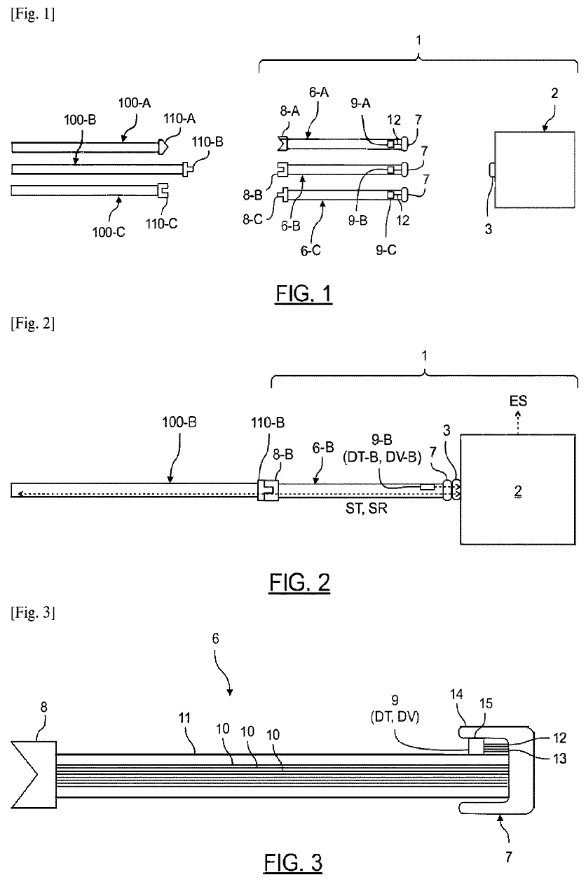

With reference to FIG. 6. the invention also relates to a method for diagnosing E the state of health of an electrical cable 100 comprising:
preferably, a step of disconnecting E0 the electrical cable 100, preferably at the level of the output connector 110 connected to the turbomachine equipment (see FIGS. 1 and 2),
preferably, a step of selecting E1 the jumper wire 6 as a function of the electrical cable 100,
a step of connecting E2, E3 the selected jumper wire 6 to the test device 2 and to the electrical cable 100,
a step of reading E4 the test data DT, and preferably the validation data DV, and
the execution of a test comprising:
   a step of transmitting E5 a test signal ST into the electrical cable 100, via the jumper wire 6, the test signal ST being determined from the test data DT,
   a step of measuring E6 a response signal SR from the electrical cable 100, via the jumper wire 6, and
   preferably, a step of comparing E7 the response signal with a reference signal Srcf, so as to determine a state of health ES of the electrical cable 100.

With reference to FIG. 1, the diagnostic method E may advantageously be implemented on board the aircraft. This allows to eliminate the need to remove and refit the various electrical cables of the aircraft. The disconnection step E0 consists of disconnecting the electrical cable 100 to be tested from the aircraft equipment to which it is connected.

With reference to FIG. 2, the selection step E2 is preferably implemented on the basis of the shape of the connector 110 of the electrical cable 100. The jumper wire 6 chosen is the one, preferably the only one, which cooperates in a form-fitting manner with the electrical cable 100, providing a keying function. It goes without saying that the selection step E2 could also be implemented on the basis of a label or a color code indicating the reference of the connector on the jumper wire 6, for example.

With reference to FIG. 3, the connection step E2 is implemented manually by the operator by connecting the output port 7 of the jumper wire 6 to the input port 3 of the test device 2. Similarly, the connection step E3 is implemented manually by the operator by connecting the input connector 8 of the jumper wire 6 to the output connector 110 of the electrical cable 100. In practice, the connection step E3 is implemented during the selection step E1.

With reference to FIG. 6, the reading step E4 is implemented by the test device 2, and more precisely the control member 5. Preferably, the control member 5 also supplies power to the data-storing element 9 during the reading step E4.

With reference to FIG. 6, the steps of transmitting E5 a test signal ST and of measuring E6 a response signal SR are implemented by the test device 2, and more precisely by the computing member 4. The test signal ST is preferably specified in a test T, supplied by the control member 5 from the test data DT. The jumper wire 6, and more specifically the electrical test leads 10, ensure the transmission of the test and response signals ST, SR between the electrical cable 100 and the measuring member 4.

Preferably, before steps E5 and E6, the execution of the test comprises a step of calibrating the test device 2 with respect to the electrical cable 100 to be checked. The calibration step is implemented by determining a tare value corresponding to the residual resistance of the electrical cable 100. The tare is then deduced from the test ST and response signals SR for a relevant measurement.

Preferably, the comparison step E7 is implemented by the test device 2, and more precisely by the control member 5, on the basis of the validation data DV. The validation data DV is used to determine a reference signal Sref to which the response signal SR is compared. The control member 5 then transmits a state of health ES of the electrical cable 100 to the display member 6. The reference signal Sref takes the form, for example, of a tolerance threshold with regard to electrical insulation and/or continuity criteria. If the response signal SR respects the tolerance threshold, the state of health ES is displayed as valid. Otherwise, the state of health ES is displayed as invalid. Preferably, the state of health ES specifies the electrical wire or wires that do not comply with the minimum and/or maximum tolerance threshold. The display member 6 may also display the response signal SR for an operator control.

Advantageously, the steps E4 to E7 allow the state of health of the connected electrical cable 100 to be checked autonomously and automatically, i.e. without operator intervention. All the operator has to do is select the appropriate jumper wire 6 and connect it to the test device 2 and to the electrical cable 100. This saves time and improves reliability, particularly when there is a large number of electrical cables 100 to be controlled in a chain, such as when maintaining the electrical cables 100 of an aircraft 500.

1.-8. (canceled)

9. A jumper wire for connecting an electrical cable to a test device for diagnosing a state of health of the electrical cable, said jumper wire comprising:
an output port configured to cooperate with an input port of the test device,
an input connector configured to cooperate with a connector of the electrical cable, the input connector being electrically connected to the output port,
at least one data-storing element comprising predetermined test data of the electrical cable, said data-storing element being electrically connected to the output port by at least one data transmission lead, said data-storing element being configured to supply the test data to the test device,
wherein the jumper wire comprises at least one electrical test lead connecting the output port to the input connector, and wherein the output port comprises a projecting portion comprising an inner face facing the electrical test lead, said data-storing element being positioned against the inner face of the projecting portion.

10. The jumper wire according to claim 9, wherein the input connector is configured to mate by shape complementarity only with the connector of the electrical cable whose test data is stored in the data-storing element.

11. The jumper wire according to claim 9, further comprising at least one power supply lead connecting the data-storing element to the output port, allowing power supply of the data-storing element by the test device.

12. A diagnostic module for diagnosing a state of health of a plurality of types of electrical cables, said diagnostic module comprising a test device and a plurality of jumper wires according to claim 9, each of the jumper wires configured to connect one type of electrical cable to the test device, the jumper wires each comprising:
an input connector of different shape configured to cooperate with a connector of one type of electrical cable,
at least one data-storing element comprising different predetermined test data from one type of electrical cable,
the test device comprising a single input port configured to co-operate alternately with the output port of each jumper wire to connect them electrically in a removable manner, the test device being configured for:
reading the test data stored in the data-storing element of the jumper wire, and
executing a test comprising: transmitting at least one test signal into the electrical cable via the jumper wire, the test signal being determined from the test data; and measuring at least one response signal of the electrical cable via the jumper wire so as to determine the state of health of the electrical cable.

13. The diagnostic module according to claim 12, wherein the test data are in the form of at least one of the following elements: code data to be executed by said test device, the selection of a test to be executed from a list of tests of the test device and/or at least one test parameter for executing a test of the test device.

14. The diagnostic module according to claim 12, wherein the data-storing element of the jumper wire also comprises validation data and the test device is configured for:
determining at least one reference signal from the validation data and
comparing the response signal with the reference signal.

15. A method of diagnosing the state of health of the plurality of types of electrical cables by means of a diagnostic module according to claim 12, test data of a type of electrical cable being initially stored in the data-storing element of each jumper wire, the diagnostic method comprising:
selecting a jumper wire whose input connector is configured to cooperate with the connector of an electrical cable,
connecting the jumper wire to the test device,
connecting the jumper wire to the electrical cable,
reading, by the test device, test data stored in the data-storing element of the jumper wire, and
executing a test comprising:
transmitting, by the test device at least one test signal into the electrical cable via the jumper wire, the test signal being determined from the test data, and
measuring, by the test device, of at least one response signal of the electrical cable, via the jumper wire, so as to determine the state of health of the electrical cable.

16. The diagnostic method according to claim 15, wherein at least one of the electrical cables is in an aircraft propulsion assembly, said electrical cable initially connecting an aircraft computer to a turbomachine equipment, said diagnostic method comprising a preliminary step of disconnecting the connector of the electrical cable and connecting the connector to the turbomachine equipment.
